(19) United States
(12) Patent Application Publication
(10) Pub. No.: US 2014/0238481 A1
(43) Pub. Date: Aug. 28, 2014

(54) SODIUM OUT-FLUX FOR PHOTOVOLTAIC CIGS GLASSES

(71) Applicant: CORNING INCORPORATED, CORNING, NY (US)

(72) Inventors: Bruce Gardiner Aitken, Corning, NY (US); James Edward Dickinson, JR., Corning, NY (US); Adama Tandia, Nelson, PA (US); Kochuparambil Deenamma Vargheese, Horseheads, NY (US)

(73) Assignees: CORNING INCORPORATED, CORNING, NY (US); CORSAM TECHNOLOGIES LLC, CORNING, NY (US)

(21) Appl. No.: 14/190,469

(22) Filed: Feb. 26, 2014

Related U.S. Application Data
(60) Provisional application No. 61/770,489, filed on Feb. 28, 2013.

(51) Int. Cl. H01L 31/0392; H01L 31/0224

(52) U.S. Cl. CPC H01L 31/03923; H01L 31/022441
USPC 136/256; 136/262

(57) ABSTRACT

Photovoltaic devices where glass substrates have a composition where (RO+M₂O)/Z₂O₃ is greater than 1. This ratio may affect sodium out-flux from the glass substrate and into the CIGS layer or the Mo layer or both.

This application claims the benefit of priority under 35 U.S.C. §119 of U.S. Provisional Application Ser. No. 61/770,489 filed on Feb. 28, 2013 the content of which is relied upon and incorporated herein by reference in its entirety.

### FIELD

The present disclosure relates to glass compositions in thin film photovoltaics, and more particularly to glass compositions in Cu(In,Ga)Se₂ (CIGS) thin film photovoltaics which may affect sodium out-flux.

### TECHNICAL BACKGROUND

Recent research has shown that there may be a correlation between copper indium gallium selenide (CuInₓGa₁₋ₓSe₂ or CIGS) module efficiency and the concentration of Sodium (Na) delivered by the glass substrate or a sodium rich layer deposited on the glass substrate. An optimal Na dosage is sought, since Na may play a role in the passivation of the grain boundary defects inside CIGS films.

### SUMMARY

Soda Lime glasses may currently perform better than other glasses as it delivers higher Na, but they have the disadvantage of low strain point temperature, which is a process limiting factor. Additionally, it has been shown that high module efficiency is enhanced when the rate of delivery of Na to the CIGS layer (i.e. Na out-diffusion or Na flux) is maximized. This has led to a search for glass substrates having compositions that deliver as much Na dosage as Soda Lime glasses, can sustain high temperature processing, and which may have thermal expansion coefficients (CTE) that can match those of CIGS materials in order to minimize the residual stress across the CIGS module.

Design of such glasses capable of optimal Na dosage delivery into the CIGS layer, and high Tₛₜᵣ is challenging since the same oxides (in the glass composition) that maximize one of these two properties, may minimize the other one. This corresponds to the need for a complex multi-property optimization. Therefore it is advantageous to determine compositional ranges which may maximize Na delivery into the CIGS layer with the optimal Na₂O content such that high strain point temperatures and high CTE are maintained.

A first aspect comprises a photovoltaic device comprising a glass substrate having a composition comprising Al₂O₃, at least one alkali metal and optionally, at least one alkali earth metal, wherein the composition satisfied the ratio (in mol %):

(RO+M₂O)/Z₂O₃≧1

wherein RO is the sum of the alkaline earth oxides in the composition, M₂O is the sum of the alkaline oxides in the composition and Z₂O₃ is the sum of Al₂O₃ and B₂O₃ in the composition; and a layer comprising copper indium gallium diselenide adjacent to the substrate. In some embodiments, the device further comprises a back contact layer disposed between the substrate and the layer. In some embodiments, the back contact layer comprises molybdenum. In some embodiments, R is the sum of CaO and MgO. In other embodiments, M is Na. In still other embodiments, Z is Al. The ratio (RO+M₂O)/Z₂O₃ can be in the range of from about 1 to about 3, about 1 to about 2, or about 1 to about 1.8.

In another aspect the glasses having the above ratios further have a strain point of 535° C. or greater and/or have a coefficient of thermal expansion of 50×10⁻⁷ or greater. In some cases, the glass substrate has a coefficient of thermal expansion of from 50×10⁻⁷ to 90×10⁻⁷.

One embodiment is a photovoltaic device comprising a glass substrate having a composition comprising RO, wherein R is an alkaline earth metal; M₂O, wherein M is an alkali metal; and Al₂O₃, and wherein (RO+M₂O)/Al₂O₃ is greater than 1; and a layer comprising copper indium gallium diselenide adjacent to the substrate.

The glass substrates or photovoltaic devices described herein may have one or more of the following advantages: fusion formability, optimum Na dosage into the CIGS layer for CIGS photovoltaic device applications, similar Na dosage into the CIGS layer as Soda Lime glasses for CIGS photovoltaic device applications, optimum Coefficient of Thermal Expansion (CTE), for example, CTE matching that of the CIGS layer (which is achievable with the increase of the alkali content), or high strain point temperatures (which is achievable with a minimal content of alkali). The glass substrates may provide the needed balance to optimize simultaneously the strain point, the CTE, and the Na delivery.

Additional features and advantages will be set forth in the detailed description which follows, and in part will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary, and are intended to provide an overview or framework to understanding the nature and character of the claims. The accompanying drawings are included to provide a further understanding, and are incorporated in and constitute a part of this specification. The drawings illustrate one or more embodiment(s), and together with the description serve to explain principles and operation of the various embodiments.

### BRIEF DESCRIPTION OF THE DRAWINGS

FIG. 1 is a graph showing the correlation between measured Na flux using secondary ion mass spectrometry (SIMS) and calculated Na flux for a set of CIGS compositions.

FIG. 2 is a graph showing the variation of Na flux with (RO+M₂O)/Al₂O₃ ratio.

FIG. 3 is a graph showing the variation of Na flux with respect to the rario of Na₂O/RO, where R is Ca (diamonds) or Mg (squares).

FIG. 4 is a graph showing variation of Na flux with (RO+M₂O)/Al₂O₃ ratio extracted from experimental SIMS data.

FIG. 5 is a graph of a linear correlation study between strain point temperature, CTE and Z₂O₃/(RO+M₂O) showing a narrow window of opportunity to find glass compositions that could maximize both strain point temperature and CTE.

FIG. 6 is a graph of normalized Na out-flux as a function of the M₂O to Z₂O₃ ratio from experimental SIMS data for a series of exemplary Na₂O*CaO*MgO*Al₂O₃*SiO₂ compositions.

### DETAILED DESCRIPTION

Reference will now be made in detail to the present preferred embodiment(s), examples of which are illustrated in the accompanying drawings. Whenever possible, the same reference numerals will be used throughout the drawings to refer to the same or like parts.

As used herein, the term “substrate” can be used to describe either a substrate or a superstrate depending on the configuration of the photovoltaic cell. For example, the substrate is a superstrate, if when assembled into a photovoltaic cell, it is on the light incident side of a photovoltaic cell. The superstrate can provide protection for the photovoltaic materials from impact and environmental degradation while allowing transmission of the appropriate wavelengths of the solar spectrum. Further, multiple photovoltaic cells can be arranged into a photovoltaic module. Photovoltaic device can describe either a cell, a module, or both.

As used herein, the term “adjacent” can be defined as being in close proximity. Adjacent structures may or may not be in physical contact with each other. Adjacent structures can have other layers and/or structures disposed between them.

Where a range of numerical values is recited herein, comprising upper and lower values, unless otherwise stated in specific circumstances, the range is intended to include the endpoints thereof, and all integers and fractions within the range. It is not intended that the scope of the invention be limited to the specific values recited when defining a range. Further, when an amount, concentration, or other value or parameter is given as a range, one or more preferred ranges or a list of upper preferable values and lower preferable values, this is to be understood as specifically disclosing all ranges formed from any pair of any upper range limit or preferred value and any lower range limit or preferred value, regardless of whether such pairs are separately disclosed. Finally, when the term “about” is used in describing a value or an end-point of a range, the disclosure should be understood to include the specific value or end-point referred to.

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such.

The term “or”, as used herein, is inclusive; more specifically, the phrase “A or B” means “A, B, or both A and B”. Exclusive “or” is designated herein by terms such as “either A or B” and “one of A or B”, for example.

The indefinite articles “a” and “an” are employed to describe elements and components of the invention. The use of these articles means that one or at least one of these elements or components is present. Although these articles are conventionally employed to signify that the modified noun is a singular noun, as used herein the articles “a” and “an” also include the plural, unless otherwise stated in specific instances. Similarly, the definite article “the”, as used herein, also signifies that the modified noun may be singular or plural, again unless otherwise stated in specific instances.

For the purposes of describing the embodiments, it is noted that reference herein to a variable being a “function” of a parameter or another variable is not intended to denote that the variable is exclusively a function of the listed parameter or variable. Rather, reference herein to a variable that is a “function” of a listed parameter is intended to be open ended such that the variable may be a function of a single parameter or a plurality of parameters.

It is noted that terms like “preferably,” “commonly,” and “typically,” when utilized herein, are not utilized to limit the scope of the claimed invention or to imply that certain features are critical, essential, or even important to the structure or function of the claimed invention. Rather, these terms are merely intended to identify particular aspects of an embodiment of the present disclosure or to emphasize alternative or additional features that may or may not be utilized in a particular embodiment of the present disclosure.

It is noted that one or more of the claims may utilize the term “wherein” as a transitional phrase. For the purposes of defining the present invention, it is noted that this term is introduced in the claims as an open-ended transitional phrase that is used to introduce a recitation of a series of characteristics of the structure and should be interpreted in like manner as the more commonly used open-ended preamble term “comprising.”

Advantageously, the composition of the glass substrates for photovoltaic CIGS applications provide simultaneous maximization of three glass properties: strain point temperature, coefficient of thermal expansion, and Na out-flux from the glass to the Mo/CIGS layer.

In one embodiment, the glass has a strain point of 535° C. or greater, for example, 540° C. or greater, for example, a strain point of 560° C. or greater, for example, a strain point of 570° C. or greater, for example, 580° C. or greater. In some embodiments, the glass has a coefficient of thermal expansion of 50×10⁻⁷ or greater, for example, 60×10⁻⁷ or greater, for example, 70×10⁻⁷ or greater, for example, 80×10⁻⁷ or greater. In one embodiment, the glass has a coefficient of thermal expansion of from 50×10⁻⁷ to 90×10⁻⁷.

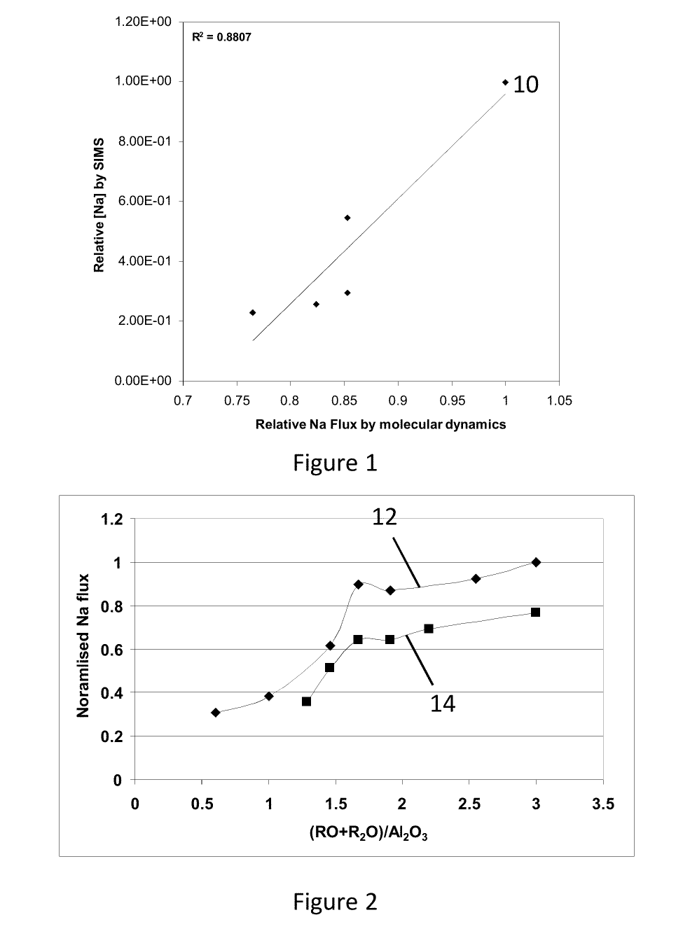

Embodiments herein are described via both actual and simulated data. FIG. 1 is a graph showing the correlation between measured Na flux using SIMS and calculated Na flux for a set of CIGS compositions. Data point 10 represents soda lime glass. Other data points represent exemplary glass compositions. Na flux is calculated using a method based on molecular dynamics. A high correlation of ˜88% between the experimentally measured and calculated values indicates the validity of the approach for screening glass compositions for CIGS as well as for deriving design rules. One of such embodiment is described in FIG. 2.

A first aspect comprises a CIGS photovoltaic device comprising a at least one glass substrate having a composition comprising the ratio in (mol %): (RO+M₂O)/Z₂O₃, wherein the ratio (RO+M₂O)/Z₂O₃ is greater than 1, and wherein RO is the sum of the alkali earth metals in the composition, M₂O is the sum of the alkali metals in the composition, and Z₂O₃ is the sum of Al₂O₃ and B₂O₃. In some embodiments, Z is Al. In some embodiments, RO is the sum of MgO and CaO. In some embodiments, M is Na. FIG. 2 exemplifies the variation of Na flux with (RO+M₂O)/Al₂O₃ ratio. The data points in FIG. 2 show the normalized Na out-flux calculated with molecular dynamics method for a series of exemplary Na₂O*CaO*MgO*Al₂O₃*SiO₂ compositions. As seen from the figure, the Na out-flux is a function of the (RO+M₂O)/Al₂O₃ ratio whether the composition contains CaO, line 12, or MgO, line 14. Na out-flux for a fixed (RO+M₂O)/Al₂O₃ ratio increases as the R₂O (e.g. Na₂O) content increases. The graph in FIG. 2 can be divided into three regions based on the slope of the lines:
Region 1: (RO+M₂O)/Al₂O₃ ratio is lower than one where the Na flux increases at a slow rate;
Region 2: (RO+M₂O)/Al₂O₃ ratio is between 1 and ˜1.8, Na flux increases at higher rate;
Region 3: (RO+M₂O)/Al₂O₃ ratio is >1.8, where again Na flux increases at a slower rate.

It is apparent from the graph in FIG. 2 that, regardless of the particular alkaline earth, compositions should have a (RO+M₂O)/Al₂O₃ ratio greater than 1 to ensure a maximum of Na out-flux. The ability to mix CaO, MgO, SrO, and BaO allows further tailoring of physical properties in addition to maximizing Na out-diffusion.

Similarly, FIG. 4 is a graph showing variation of Na flux with (RO+M₂O)/Al₂O₃, wherein the ratio is extracted from experimental SIMS data. This variation of the alkali flux with (RO+M₂O)/Al₂O₃ agrees well with the predicted trend from molecular dynamics simulations and therefore validates the design rule proposed using molecular dynamics simulations.

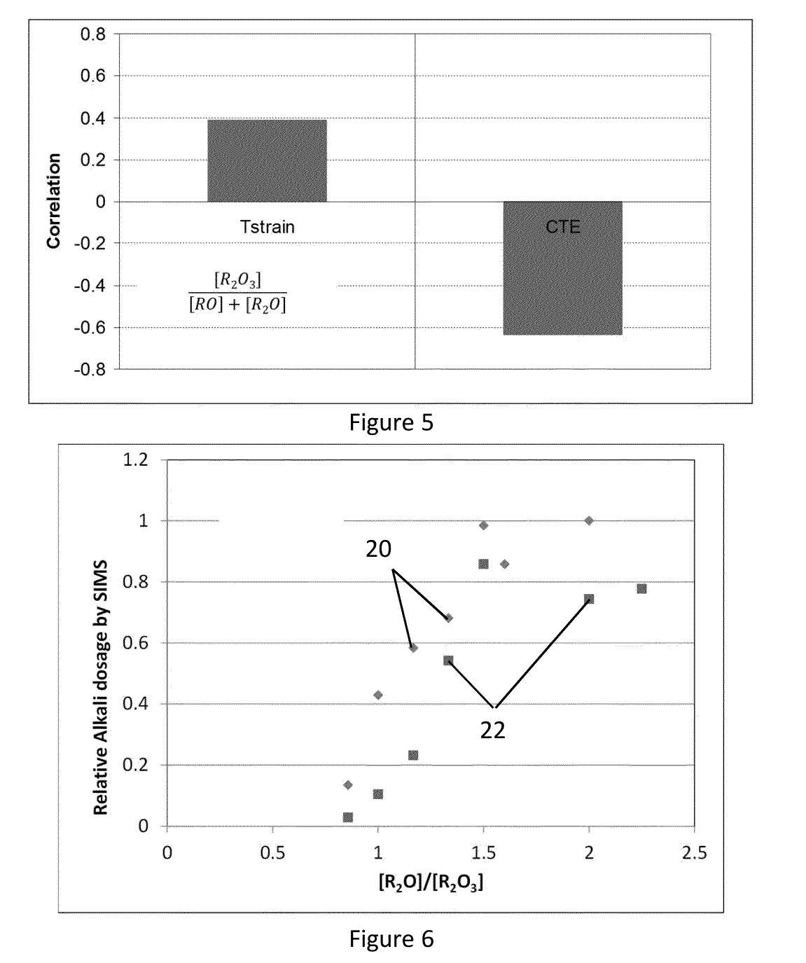

The glasses embodied herein and devices incorporating these glasses provide an unexpected advantage in that they balance a number of critical factors necessary in CIGS photovoltaic devices. FIG. 5 describes a linear correlation study between strain point temperature, CTE and Z₂O₃/(RO+M₂O). The large positive and negative correlations of Tstrain and CTE with ratio of Z₂O₃/(RO+M₂O) show that there is very narrow window of glass compositions that maximize both strain point temperature and CTE. The difference in the amplitudes of the correlations of 1/[(RO+M₂O)/Z₂O₃] with both strain point temperature (Tstrain) and Coefficient of Thermal Expansion (CTE) is indicative of the existence of exemplary compositions that allow the maximization of both properties.

The linear correlation between 1/[(RO+M₂O)/Z₂O₃] (“1/Y”) and CTE and Strain point shows an increase of the strain point temperature with the an increase of the 1/Y, and a decrease of CTE with an increase of 1/Y. Had the amplitudes of both CTE and strain point variations be of equal value, there would have been no way of using 1/Y to increase the CTE without decreasing the strain point. From FIG. 5 it becomes obvious that there only exist a small window for such design: use of RO and R₂O to increase the CTE and Na out-flux will ultimately induce a reduction of the strain point temperature. It is advantageous to find the interplay between the different oxides to maximize all three key properties. The procedure that drives the design resides on finding the minimal value of the ratio Y=(RO+M₂O)/Z₂O₃ that saturates the Na out-flux while maximizing both the CTE and the strain point temperature.

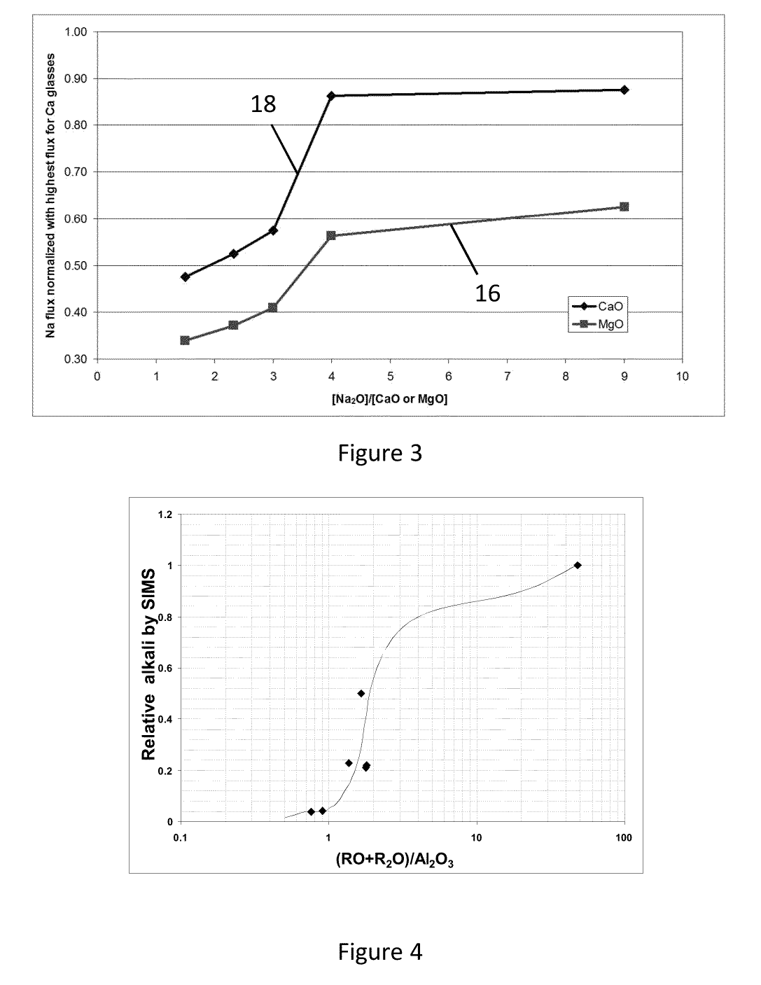

In another aspect, the Na flux from a glass substrate correlates with the ratio of M₂O/RO. In some embodiments, R is Mg or Ca. In some embodiments, M is Na. FIG. 3 is a graph showing the variation of Na flux with respect to M₂O/RO where R is Ca or Mg. A saturation of Na flux is found when X>4. The Na flux increases when MgO, Line 16, is substituted with CaO, Line 18.

In another aspect, the Na out flux from a glass substrate correlates with the ratio of M₂O/Z₂O₃. In some embodiments, R is Mg or Ca. In some embodiments, M is Na. FIG. 6 is a graph of normalized Na out-flux as a function of the M₂O to Z₂O₃ ratio from experimental SIMS data for a series of exemplary Na₂O*CaO*MgO*Al₂O₃*SiO₂ compositions. The Na out-flux is a function of the M₂O/Z₂O₃ ratio, whether the composition contains CaO or MgO. Small data points 20 represent glass compositions containing CaO. Large data points 22 represent glass compositions containing MgO.

It will be apparent to those skilled in the art that various modifications and variations can be made without departing from the spirit or scope of the invention.

What is claimed is:

1. A photovoltaic device comprising:
a glass substrate having a composition comprising Al₂O₃, at least one alkali metal and optionally, at least one alkali earth metal, wherein the composition satisfied the ratio (in mol %):
(RO+M₂O)/Z₂O₃≧1
wherein RO is the sum of the alkaline earth oxides in the composition, M₂O is the sum of the alkaline oxides in the composition and Z₂O₃ is the sum of Al₂O₃ and B₂O₃ in the composition; and
a layer comprising copper indium gallium diselenide adjacent to the substrate.

2. The device according to claim 1, further comprising a back contact layer disposed between the substrate and the layer.

3. The device according to claim 2, wherein the back contact layer comprises molybdenum.

4. The device according to claim 1, wherein R is the sum of CaO and MgO.

5. The device according to claim 1, wherein M is Na.

6. The device according to claim 1, wherein (RO+M₂O)/Z₂O₃ is in the range of from about 1 to about 3.

7. The device according to claim 1, wherein (RO+M₂O)/Z₂O₃ is in the range of from about 1 to about 2.

8. The device according to claim 1, wherein the glass substrate has a strain point of 535° C. or greater.

9. The device according to claim 1, wherein the glass substrate has a coefficient of thermal expansion of 50×10⁻⁷ or greater.

10. The device according to claim 1, wherein the glass substrate has a coefficient of thermal expansion of from 50×10⁻⁷ to 90×10⁻⁷.

11. The device according to claim 1, wherein (RO+M₂O)/Z₂O₃ is in the range of from about 1 to about 2, Z is Al, the glass substrate has a strain point of 535° C. or greater, and the glass substrate has a coefficient of thermal expansion of 50×10⁻⁷ or greater.

12. The device according to claim 1, wherein Z is Al.
